(19) United States
(12) Patent Application Publication
(10) Pub. No.: US 2009/0101494 A1
(43) Pub. Date: Apr. 23, 2009

(54) Method for Producing Internal Antenna with Anti-Electromagnetic Interference Property Through Vacuum Process

(75) Inventors: Cheng-Tao WU, Kaohsiung City (TW); Ping-Chen CHANG, Pingtung County (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: MITAC PRECISION TECHNOLOGY CORPORATION, Jiangsu (CN)

(21) Appl. No.: 12/176,708

(22) Filed: Jul. 21, 2008

(30) Foreign Application Priority Data
Oct. 19, 2007 (CN) 200710134774.3

(51) Int. Cl. C23C 14/34

(52) U.S. Cl. 204/192.15

(57) ABSTRACT

A method for producing an internal antenna with an anti-electromagnetic interference property by performing a vacuum process, which includes (1) performing a surface pretreatment process on an insulating substrate to clean the surface thereof, (2) placing the substrate into a vacuum chamber, and performing a first plasma bombardment by using a conductive target material; (3) placing the substrate into another vacuum chamber, and performing a second plasma bombardment by using a passivation target material; (4) removing a certain part of the passivation layer and the conductive layer, such that a planar antenna pattern is remained with a certain distance spaced apart from the surrounding passivation layer and conductive layer. The conductive layer and the passivation layer cover the surface of the substrate for completely shielding the electromagnetic interference, and meanwhile, the planar shape of the antenna saves the cost and the available space within the housing.

### CROSS-REFERENCE TO RELATED APPLICATIONS

This non-provisional application claims priority under 35 U.S.C. §119(a) on Patent Application No(s). 200710134774.3 filed in China, P.R.C. on Oct. 19, 2007 the entire contents of which are hereby incorporated by reference.

### BACKGROUND OF THE INVENTION

1. Field of the Invention

The present invention relates to a method for producing an internal planar antenna on a substrate by performing a vacuum coating process and meanwhile achieving an anti-electromagnetic interference function.

2. Related Art

Antenna acts as a key component for transmitting and receiving radio electromagnetic waves in wireless technology (at least including the fields of wireless telecommunication, and wireless data transmission). The transmitting antenna is used to convert the current and voltage generated by the transmitter into electromagnetic waves, and to spread the electromagnetic waves in the air by means of radiation. The receiving antenna intercepts the electromagnetic waves, converts them back to current and voltage, and then processes the current and voltage in the receiver. Therefore, the electrical characteristic of the antenna is sufficient for influencing the quality of wireless technology.

As for the antennas of electronic devices in the current market, such as dipole antennas, panel antennas, PIFA antennas, or relatively complicated array antennas or smart antennas, some manufacturers hide the antenna within the electronic device, and most of them fabricate the antenna individually and then connect the antenna to the antenna module circuit within the housing of the electronic device. FIG. 1 shows the allocation relationship of the antenna in the conventional electronic device. The electronic device 1 has a housing 11, a backlight module 12, an anti-electromagnetic interference (EMI) control plate 13, and a second housing 14. An antenna 15 is disposed on the inner surface of the second housing 14 and connected to an antenna module 171 of a motherboard 17 for the electronic device through an antenna feed-in line 16, so as to transmit the radio signal generated by the antenna module 171 to the antenna 15, or to transmit the radio signal received by the antenna 15 to the antenna module 171.

The signal may be transmitted between the antenna module and the antenna in a coupling sensing way, that is, a feed-in line is connected to a coupling component, and the coupling component is coupled to an antenna for transmitting signals, and the antenna is not connected to the coupling component.

In the above cases, an aluminum foil is attached to an inner surface within the housing of the electronic device for preventing electromagnetic interference, then a copper foil is attached to the aluminum foil as a ground region for the antenna, and the body of the antenna is placed in the insulating region at the edge of the aluminum foil, thereby having the following two defects: 1. the aluminum foil is missing at the inner side edge, and cannot cover the whole inner surface, and thus a part of electromagnetic waves are leaked; 2. the antennas are fabricated individually, and most of them are fixed at the inner edge of the housing, thereby having a high manufacturing cost and a complicated assembling process.

### SUMMARY OF THE INVENTION

The present invention is directed to a method for producing an internal antenna by performing a vacuum process and meanwhile achieving an anti-electromagnetic interference effect.

As embodied and broadly described herein, the present invention provides a method for producing an internal antenna with anti-electromagnetic interference property by performing a vacuum process, which includes the following steps: (a) providing an insulating substrate, and performing a surface pretreatment process on the substrate to clean the surface thereof, (b) performing a vacuum process, including two steps: (b-1) sputtering a conductive layer: placing the substrate into a vacuum chamber, and performing a first plasma bombardment by using a conductive target material, such that the surface components of the conductive target material are sputtered in the form of atoms for being deposited and covered on the whole substrate, so as to form the conductive layer; (b-2) sputtering a passivation layer: placing the substrate into another vacuum chamber, and performing a second plasma bombardment by using a passivation target material, such that the surface components of the passivation target material are sputtered in the form of atoms for being deposited and covered on the conductive layer, so as to form the passivation layer; (c) removing a certain part of the passivation layer and the conductive layer, such that a planar antenna pattern is remained with a distance spaced apart from the surrounding passivation layer and conductive layer.

Compared with the conventional art, the vacuum process is adopted to cover the substrate with the conductive layer and the passivation layer, so as to totally shield the electromagnetic interference, and meanwhile, the costs of the planar shape of the antenna can be decreased and the available space within the housing can be also reduced. Furthermore, there may be a plurality of antennas, and their allocation positions and patterns may be changed optionally, and thus meeting the requirements of transmitting radio signals through multiple frequencies. Furthermore, the manufacturing process and technology are quite simple, which are suitable for mass production, and hardly produce any waste, thus protect environment.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1 is a schematic view of the allocation of an antenna for an electronic device in the conventional art.

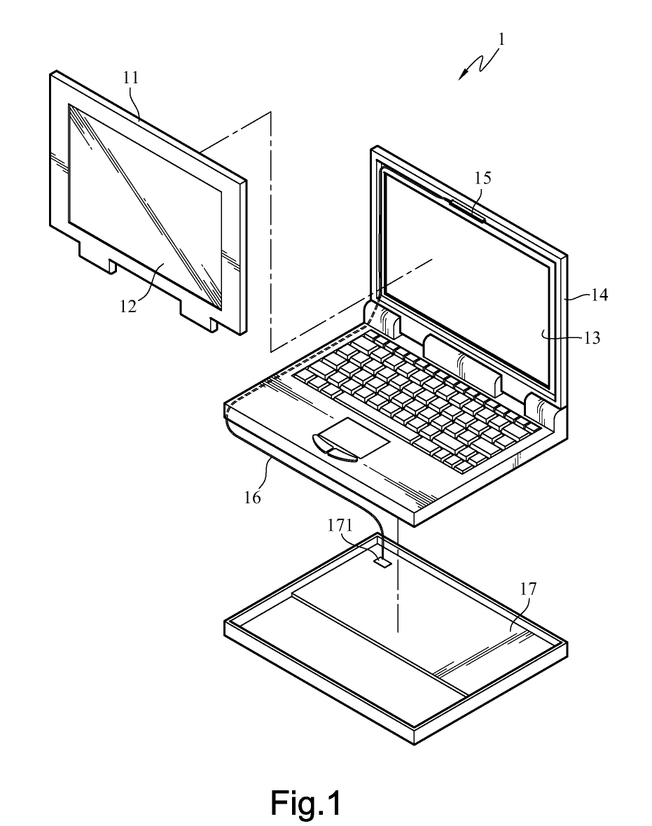

FIG. 2 is a flow chart of the allocation of the method for producing an internal antenna with anti-electromagnetic interference property in the present invention.

### DETAILED DESCRIPTION OF THE INVENTION

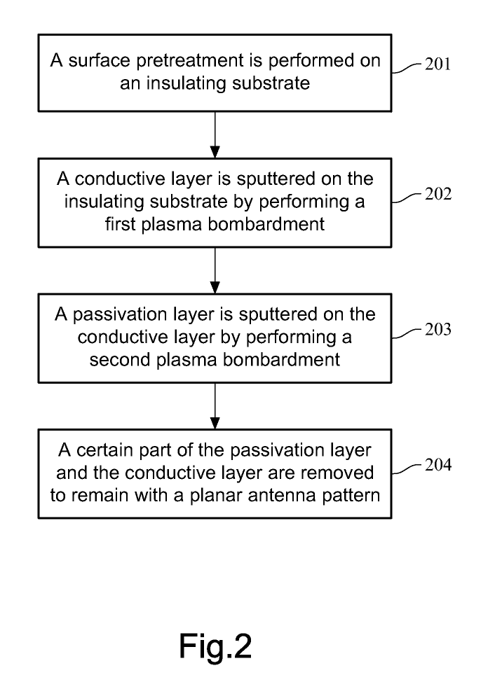

The method for producing an internal antenna with anti-electromagnetic interference property by performing a vacuum process in the present invention includes the following steps shown as FIG. 2.

Step 201. An insulating substrate is provided, which may be plastic insulating material, such as polycarbonate (PC), a mixture of PC and acrylonitrile butadiene styrene copolymer (PC+ABS), a mixture of PC and fiber (PC+fiber), a mixture of PC, ABS, and fiber (PC+ABS+fiber), or nylon (PA) or a mixture of nylon and fiber (PA+fiber). Then, a surface pretreatment is performed on the substrate particularly, which includes steps of degreasing, ultrasonic cleaning, and drying to clean the surface thereof. The substrate is usually used as an inner surface for a plastic housing.

A conductive layer and a passivation layer are sputtered in vacuum, which particularly includes the following steps.

In Step 202, a conductive layer is sputtered on the insulating substrate The insulating substrate is placed into a vacuum chamber, and Cu or Ag is used as a conductive target material. Then, a first plasma bombardment is performed by using the conductive target material, such that the surface components of the conductive target material are sputtered in the form of atoms for being deposited on the insulating substrate surface, so as to form the conductive layer. The conductive layer has a thickness of 0.3-5 μm.

Alternatively, a first evaporation process is performed in a vacuum chamber to vaporize a conductive material, such as Cu or Ag. Next, after performing a cooling process, the conductive material is deposited on the surface of the insulating substrate, so as to form the conductive layer. The conductive layer has a thickness of 0.3-5 μm;

Thereby, the conductive layer covers the whole surface of the substrate;

In Step 203, a passivation layer is sputtered.

The substrate is placed into another vacuum chamber, and stainless steel, Ni, Cr, or Ni—Cr alloy are used as passivation target material. Then, a second plasma bombardment is performed by using a passivation target material, such that the surface components of the passivation target material are sputtered in the form of atoms for being deposited on the surface of the conductive layer on the substrate, so as to form the passivation layer to prevent the conductive layer from being oxidized. The passivation layer has a thickness of 0.1-0.5 μm.

Alternatively, a second evaporation process is performed in a vacuum chamber to vaporize a passivation material, such as stainless steel, Ni, Cr, or Ni—Cr alloy. Then, after performing a cooling process, the passivation material is deposited on the surface of the conductive layer on the substrate, so as to form the passivation layer. The passivation layer has a thickness of 0.1-0.5 μm.

Thereby, the passivation layer covers the above conductive layer.

Steps (202) and (203) may be performed in the same vacuum chamber, that is, the coating material of the conductive layer and the coating material of the passivation layer are both placed in the vacuum chamber, and then they are bombarded or vaporized respectively by controlling voltage, current and temperature to sequentially deposit the conductive layer and the passivation layer on the surface of the substrate.

Step 204. A certain part of the passivation layer and the conductive layer is removed by performing a laser carving technique, such that a planar antenna pattern is remained with a distance of 2-10 mm spaced apart from the surrounding passivation layer and conductive layer. Thus, the substrate with a width of 2-10 mm is exposed.

Based on the above, the allocation position of the planar antenna pattern is no longer restricted to the edge of the housing, and particularly, the allocation position and the change of the antenna pattern can be controlled according to the different application fields of the antenna structure.

To sum up, since the vacuum process including vacuum sputtering and vacuum evaporation is adopted to completely cover the surface of the substrate with the conductive layer and the passivation layer, so as to shield the electromagnetic interference completely. Furthermore, the costs for manufacturing individual planar antenna can be decreased and the available space within the housing can be also reduced. Furthermore, there may be a plurality of antennas, and their positions and patterns can be changed optionally, which thus meets the requirements of transmitting radio signal through multiple frequencies.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for producing an internal antenna with anti-electromagnetic interference property by performing a vacuum process, comprising:
(a) performing a surface pretreatment process on an insulating substrate to clean the surface of the insulating substrate;
(b) performing a vacuum process, comprising:
(b-1) sputtering a conductive layer on the insulating substrate, wherein the insulating substrate is placed into a vacuum chamber and a first plasma bombardment is performed by using a conductive target material, such that surface components of the conductive target material are sputtered in a form of atoms for being deposited and covered on the whole insulating substrate;
(b-2) sputtering a passivation layer on the conductive layer, wherein the insulating substrate is placed into another vacuum chamber, and a second plasma bombardment is performed by using a passivation target material, such that surface components of the passivation target material are sputtered in as a form of atoms for being deposited and covered on the conductive layer; and
(c) removing a certain part of the passivation layer and the conductive layer, so that a planar antenna pattern is remained with a certain distance spaced apart from the surrounding passivation layer and conductive layer.

2. The method for producing the internal antenna with anti-electromagnetic interference property by performing a vacuum process as claimed in claim 1, wherein the conductive layer comprises Cu or Ag.

3. The method for producing the internal antenna with anti-electromagnetic interference property by performing a vacuum process as claimed in claim 1, wherein thickness of the conductive layer is 0.3-5 μm.

4. The method for producing the internal antenna with anti-electromagnetic interference property by performing a vacuum process as claimed in claim 1, wherein the passivation layer comprises stainless steel, Ni, Cr, or Ni—Cr alloy.

5. The method for producing the internal antenna with anti-electromagnetic interference property by performing a vacuum process as claimed in claim 1, wherein thickness of the passivation layer is 0.1-0.5 μm.

6. The method for producing the internal antenna with anti-electromagnetic interference property by performing a vacuum process as claimed in claim 1, wherein the insulating substrate comprises polycarbonate (PC), a mixture of PC and acrylonitrile butadiene styrene (ABS) copolymer, a mixture of PC and fiber, a mixture of PC, ABS, and fiber, nylon or a mixture of nylon and fiber.

7. The method for producing the internal antenna with anti-electromagnetic interference property by performing a vacuum process as claimed in claim 1, wherein a laser carving technique is performed in Step (c) for the removing process.

8. The method for producing the internal antenna with anti-electromagnetic interference property by performing a vacuum process as claimed in claim 1, wherein the antenna pattern is spaced apart from the surrounding passivation layer and conductive layer for 2-10 mm.

9. The method for producing the internal antenna with anti-electromagnetic interference property by performing a vacuum process as claimed in claim 1, wherein the surface pretreatment in Step (a) comprises degreasing, ultrasonic cleaning, and drying.

10. The method for producing the internal antenna with anti-electromagnetic interference property by performing a vacuum process as claimed in claim 1, wherein Steps (b-1) and (b-2) are performed in the same vacuum chamber.

11. A method for producing an internal antenna with anti-electromagnetic interference property by performing a vacuum process, comprising:
(a) performing a surface pretreatment process on an insulating substrate to clean the surface of the insulating substrate;
(b) performing a vacuum process, comprising:
(b-1) sputtering a conductive layer on the insulating substrate, wherein the insulating substrate is placed into a vacuum chamber and a first evaporation process is performed to vaporize a conductive material, such that the conductive material is deposited on the whole insulating substrate to form the conductive layer after performing a cooling process;
(b-2) sputtering a passivation layer on the conductive layer, wherein the insulating substrate is placed into another vacuum chamber, and a second evaporation process is performed to vaporize a passivation material, such that the passivation material is deposited on the conductive layer to form the passivation layer after performing a cooling process; and
(c) removing a certain part of the passivation layer and the conductive layer, so that a planar antenna pattern is remained with a certain distance spaced apart from the surrounding passivation layer and conductive layer.

12. The method for producing the internal antenna with anti-electromagnetic interference property by performing a vacuum process as claimed in claim 11, wherein the conductive layer comprises Cu or Ag.

13. The method for producing the internal antenna with anti-electromagnetic interference property by performing a vacuum process as claimed in claim 11, wherein thickness of the conductive layer is 0.3-5 μm.

14. The method for producing the internal antenna with anti-electromagnetic interference property by performing a vacuum process as claimed in claim 11, wherein the passivation layer comprises stainless steel, Ni, Cr, or Ni—Cr alloy.

15. The method for producing the internal antenna with anti-electromagnetic interference property by performing a vacuum process as claimed in claim 11, wherein thickness of the passivation layer is 0.1-0.5 μm.

16. The method for producing the internal antenna with anti-electromagnetic interference property by performing a vacuum process as claimed in claim 11, wherein the insulating substrate comprises polycarbonate (PC), a mixture of PC and acrylonitrile butadiene styrene (ABS) copolymer, a mixture of PC and fiber, a mixture of PC, ABS, and fiber, nylon or a mixture of nylon and fiber.

17. The method for producing the internal antenna with anti-electromagnetic interference property by performing a vacuum process as claimed in claim 11, wherein a laser carving technique is performed in Step (c) for the removing process.

18. The method for producing the internal antenna with anti-electromagnetic interference property by performing a vacuum process as claimed in claim 11, wherein the antenna pattern is spaced apart from the surrounding passivation layer and conductive layer for 2-10 mm.

19. The method for producing the internal antenna with anti-electromagnetic interference property by performing a vacuum process as claimed in claim 11, wherein the surface pretreatment in Step (c) comprises degreasing, ultrasonic cleaning, and drying.

20. The method for producing the internal antenna with anti-electromagnetic interference property by performing a vacuum process as claimed in claim 11, wherein Steps (b-1) and (b-2) are performed in the same vacuum chamber.
